(19) United States
(12) Patent Application Publication
(10) Pub. No.: US 2008/0048244 A1
(43) Pub. Date: Feb. 28, 2008

(54) NONVOLATILE MEMORY, NONVOLATILE MEMORY ARRAY AND MANUFACTURING METHOD THEREOF

(75) Inventors: Chih-Wei Hung, Hsin-chu City (TW); Cheng-Yuan Hsu, Hsinchu City (TW); Da Sung, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 11/930,178

(22) Filed: Oct. 31, 2007

Related U.S. Application Data
(63) Continuation of application No. 11/160,104, filed on Jun. 9, 2005.
Application No. 11/160,104 is a continuation-in-part of application No. 10/904,478, filed on Nov. 12, 2004, now Pat. No. 7,180,128.

(30) Foreign Application Priority Data
May 12, 2004 (TW) 93113274
Jan. 13, 2005 (TW) 94100956

(51) Int. Cl. H01L 29/788

(52) U.S. Cl. 257/316; 257/E29.3

(57) ABSTRACT

A nonvolatile memory includes a substrate, stacked gate structures, spacers, control gates, a composite dielectric layer and source region/drain regions. Each of stack gate structures is formed on the substrate and is consisted of a select gate dielectric layer, a select gate and a cap layer. The spacers are disposed on the sidewalls of the stack gate structure. The composite dielectric layer including a bottom dielectric layer, a charge trapping layer and upper dielectric layer is formed on the substrate. The control gates, which filled in the spaces between the stacked gate structures, are disposed on the composite dielectric layer and connected to each other. The source region/drain region is configured in the substrate near the outer two stacked gate structures.

### CROSS-REFERENCE TO RELATED APPLICATION

This application is a continuation of a prior application Ser. No. 11/160,104, filed Jun. 9, 2005, which claims the priority benefits of Taiwan application No. 94100956, filed on Jan. 13, 2005 and Taiwan application No. 93113274, filed on May 12, 2004. The prior application Ser. No. 11/160,104 is a continuation-in-part of a prior application Ser. No. 10/904,478, of U.S. Pat. No. 7,180,128 B2, which claims the priority benefits of Taiwan application No. 93113274, filed on May 12, 2004. The entirety of each of the above-mentioned patent and patent applications is hereby incorporated by reference herein and made a part of this specification.

### BACKGROUND OF THE INVENTION

1. Field of the Invention

The present invention relates to a semiconductor device. More particularly, the present invention relates to a non-volatile memory (NVM), a non-volatile memory array and a manufacturing method thereof.

2. Description of Related Art

Electrically erasable programmable read only memory (EEPROM) is a type of non-volatile memory that allows multiple data reading, writing and erasing operations. In addition, the stored data will be retained even after power to the device is removed. With these advantages, electrically erasable programmable read only memories have been broadly applied in personal computers and electronic equipment.

A typical flash memory device has a floating gate and a control gate fabricated with doped polysilicon. During an erasing operation by a typical EEPROM device, a critical over-erasure often occurs, leading to a misinterpretation of the data. To prevent such an event from occurring, a select gate is designed on the sidewalls of the control gate and the floating gate and the substrate to form a split gate structure.

Currently, the industry provides a fabrication method for a split-gate memory cell of the AG-AND type of memory array structure as described in U.S. Pat. No. 6,567,315. FIG. 1 is a schematic cross-sectional view of a portion of a conventional AG-AND type of memory cell structure.

Referring to FIG. 1, an AG-AND type of memory cell structure includes a substrate 100, a well region 102, and an auxiliary gate transistor Qa1 (Qa2), a memory device Qm1 (Qm2), and source/drain regions 104a, 104b (104c) that are disposed in the substrate 100 besides the two sides of the auxiliary gate transistor Qa1 (Qa2) and the memory device Qm1 (Qm2). The auxiliary gate transistor Qa1 (Qa2) includes an auxiliary gate 106a (106b). The memory device Qm1 (Qm2) includes a floating gate 108a (108b) and a word line 110, wherein the word line 110 serves as a control gate of the memory device Qm1 (Qm2). The auxiliary gate transistor Qa1 (Qa2) and the memory device Qm1 (Qm2) constitute a memory cell Q1 (Q2). Further, the neighboring memory cells along a same row in the AG-AND array share a common source/drain region.

In the above AG-AND type of memory cell structure, when a memory cell Q1 is performing the programming operation, a bias voltage of 13 volts is applied to the word line, a bias voltage of 1 volt is applied to the auxiliary gate 106a, a bias voltage of 0 volt is applied to the source/drain region 104a, and a bias voltage of 5 volts is applied to the source/drain region 104b for electrons to be injected into the floating gate 108a of the memory device Qm1 to program the memory cell Q1. Since no voltage is applied to the auxiliary gate 106b, the memory cell Q2 is not programmed.

However, in the above AG-AND type of memory cell structure, the source/drain regions (104a, 104b or 104c) are formed in the substrate 100 beside the two sides of the memory cell Q1 (Q2). To prevent the source/drain regions (104a, 104b or 104c) from being too close and the channel underneath the memory cell from being conductive, the source/drain regions need to be parted at a certain distance. Accordingly, the dimension of the memory cell can not be further reduced.

### SUMMARY OF THE INVENTION

The present invention provides a non-volatile memory device and a non-volatile memory array and a fabrication method thereof. No only the fabrication of the non-volatile memory array is simple, this type of non-volatile memory device can also apply source-side injection (SSI) to perform the programming operating in order to increase the programming speed and to improve efficiency of the memory cell.

The present invention also provides a non-volatile memory, a non-volatile memory array and a fabrication method thereof, wherein the operation voltage of the memory can increase to raise the efficiency of the device.

The present invention further provides a non-volatile memory, a non-volatile memory array and a fabrication method thereof, wherein the memory cell device can be reduced to increase the integration of the device.

The present invention provides a non-volatile memory. The non-volatile memory includes a first row of memory cells, a first source/drain region and a second source/drain region. The first row of memory cells includes a plurality of stacked gate structures, a spacer, a plurality of control gates, a composite dielectric layer. The plurality of stacked gate structures is disposed on the substrate, wherein each stacked gate structure includes a select gate dielectric layer, a select gate and a cap layer, sequentially formed from the substrate. The spacer is disposed on the sidewall of the stacked gate structure. The composite dielectric layer is disposed on the substrate, wherein the composite dielectric layer includes a bottom dielectric layer, a charge trapping layer and a top dielectric layer. A control gate line is disposed above the composite dielectric layer, filling the gaps between every two stacked gate structures. The first source/drain region and the second source/drain region are respectively disposed in the substrate beside the two sides of the first row of memory cells. The above non-volatile memory further includes a second row of memory cells and a third second source/drain region and a third source/drain region disposed on the substrate. The second row of memory cells and the first row of memory cells have similar structures. The second source/drain region and the third source/drain region are disposed in the substrate respectively besides two sides of the second row of memory cells, wherein the first row of memory cells and the second row memory cells share the second source/drain region.

In the structure of the non-volatile memory of the present invention, no isolation structure and no contact are formed between each row of the memory cells. The integration of the memory cell array can thereby increase.

The present invention also provides a non-volatile memory cell array. The memory cell array includes a substrate, a plurality of rows of memory cells, a plurality of control gate lines, a plurality of select gate lines, a plurality of source lines and a plurality of drain lines. The plurality of rows of memory cells is arranged into a memory array, wherein the memory array includes a plurality of stacked gate structures disposed on the substrate. Each stacked gate structure includes, sequentially from the substrate, a select gate dielectric layer, a select gate and a cap layer. A spacer is disposed on the sidewall of the stacked gate structure, and the composite dielectric layer is disposed on the substrate. The composite dielectric layer includes a bottom dielectric layer, a charge trapping layer and a top dielectric layer. A plurality of control gates is disposed above the composite dielectric layer between every two stacked gate structures. The source/drain regions are disposed in the substrate respectively beside one side of the two outer stacked gate structures. The plurality of the control gate lines connects the control gates of a same row of the memory cells. A plurality of select gate lines connects the select gates of a same column of the memory cells. A plurality of source lines connects the source regions along a same column, while a plurality of drain lines connects the drain regions along a same column.

The above-mentioned non-volatile memory array can be divided into at least a first memory block and a second memory block. The drain regions of different rows of memory cells in the first memory block are connected through the first drain line, and the drain regions of different rows of memory cells in the second memory block are connected through the second drain line. Further, the first memory block and the second memory block share a source line.

The above-mentioned memory array can apply the source-side injection to inject electrons into the charge trapping layer of a selected memory cell to program the selected memory cell. Further, the above-mentioned memory array can also apply the channel F-N tunneling to eject electrons from the charge trapping layer of the memory cell to the substrate to erase all information from the entire memory cell array.

In the non-volatile memory cell array of the present invention, there is no gap presents in between the memory cell structures. The integration of the memory cell array can thereby increase.

The present invention provides a fabrication method for a non-volatile memory, wherein a substrate is first provided and a plurality of stacked gate structures is already formed over the substrate. Each of the stacked gate structures includes a select gate dielectric layer, a select gate and a cap layer. A source region and a drain region are subsequently formed in the substrate. The source region and the drain region are separated by at least two stacked gate structures. A composite dielectric layer is formed over the substrate, followed by forming a conductive layer over the substrate. The conductive layer is further patterned to form a plurality of connecting control gates that fill the gaps between the stacked gate structures.

During the fabrication method of a non-volatile memory of the present invention, a charge trapping layer (silicon nitride) is used as a charge storage unit. Accordingly, the operating voltage required by an operation can be reduced and the operating speed and efficiency of the memory cell can be improved.

Moreover, using the charge trapping layer (silicon nitride) as a charge storage unit, the process for defining a floating gate when a floating gate is used as a charge storage unit can be omitted. Ultimately, not only the fabrication process is simpler, the integration of the memory array is increased.

Further, no device isolation structure is formed between each row of the memory cells. Therefore, the process is simpler and the integration of the memory array is enhanced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic, cross-sectional view of a portion of a conventional AG-AND type of memory cell structure.

FIG. 2A is a schematic top view of a non-volatile memory array of the present invention.

FIG. 2B is a schematic, cross-sectional view of FIG. 2A, along the cutting line A-A′.

FIGS. 3A through 3D are schematic cross-sectional views showing the steps for fabricating a non-volatile memory according to an embodiment of the present invention.

FIG. 4 is a simplified circuit diagram of the non-volatile memory of the present invention.

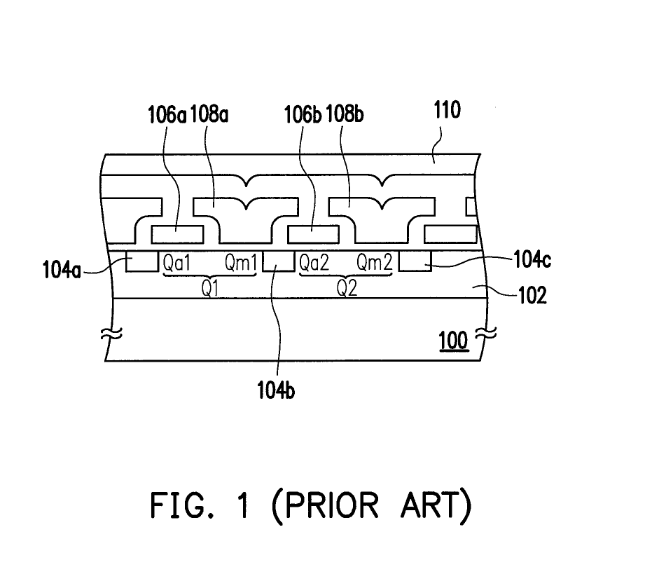

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

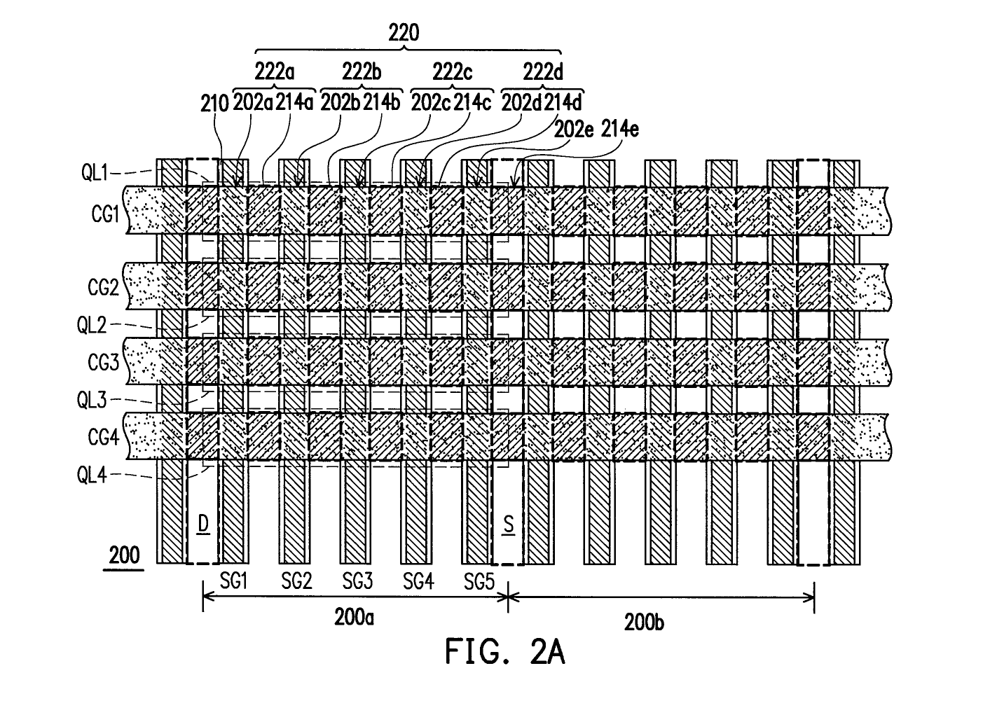

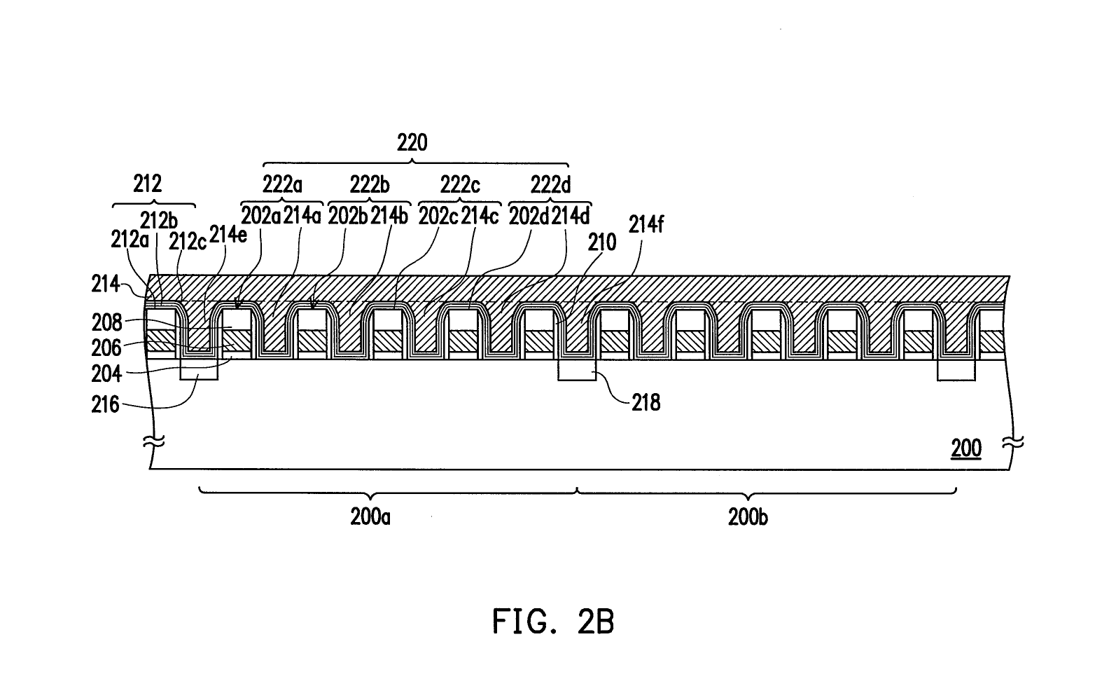

FIG. 2 is a schematic top view of a non-volatile memory array of the present invention. FIG. 2B is a schematic, cross-sectional view of FIG. 2A along the cutting line A-A′. As shown in FIG. 2A and 2B, the memory cell array can be divided into memory block 200a and memory block 200b, wherein the memory block region 200a and the memory block region 200b share a source region 220 (source line S). The following disclosure is directed to only memory block 200a.

Referring to FIG. 2A, the non-volatile memory array of the invention includes a substrate 200, a plurality of rows of memory cells QL1 to QL4, a plurality of control gate lines CG1 to CG4, a plurality of select gate lines SG1 to SG5, a source line S and a drain line D.

The rows of memory cells QL1 to QL4 are arranged in a memory array. Each of the control gate lines CG1 to CG4 connects the control gates of the memory cells of a same row. The select gates along a same column of the memory cells are respectively connected by the select gate lines SG1 to SG5. The source line S connects the source regions of a same column of the memory cells and the drain line connects the drain regions of a same column of the memory cells.

The structure of the non-volatile memory cell array of the present invention is illustrated herein with the row of the memory cells QL1.

Referring concurrently to FIG. 2A and 2B, the non-volatile memory structure of the present invention is at least formed with a substrate 200, a plurality of stacked gate structures 202a to 202e (each of the stacked gate structures 202a to 202e includes, sequentially from the substrate 200, a select gate dielectric layer 204, a select gate 206, a cap layer 208), a spacer 210, a composite dielectric layer 212 (the composite dielectric layer 212 includes, sequentially from the substrate 200, a bottom dielectric layer 212a, a charge trapping layer 212b and a top dielectric layer 212c), a plurality of control gates 214a to 214d, source regions 216, and drain regions 218.

The substrate 200 is, for example, a silicon substrate. The plurality of stacked gate structures 202a to 202e are disposed on the substrate 200, wherein the stacked gate structures 202a to 202e display, for example, a strip pattern. The thickness of the stacked gate structures 202a to 202e is about 2000 angstroms to 3500 angstroms. The material of the select gate dielectric layer 204 includes silicon oxide, for example, and the select gate dielectric layer 204 is about 160 angstroms to about 170 angstroms thick. The select gate 206, which is about 600 angstroms to about 1500 angstroms thick, is formed with, for example, doped polysilicon. The material of the cap layer 208 includes silicon oxide, and the cap layer 208 is about 1000 angstroms to about 1500 angstroms thick. The spacer 210 is disposed on the sidewall of each stacked gate structure 202a to 202e, wherein the material of the spacer 210 includes but not limited to silicon oxide or silicon nitride.

The composite dielectric layer 212 is disposed on the substrate 200. The composite dielectric layer 212 is formed with, sequentially from the substrate 200, a bottom dielectric layer 212a, a charge trapping layer 212b and a top dielectric layer 212c. The material of the bottom dielectric layer 212a includes silicon oxide, for example. Further, the bottom dielectric layer 212a is about 20 angstroms to about 60 angstroms thick. The charge trapping layer 212b is about 30 angstroms to about 70 thick, and is formed with silicon nitride, for example. The material of the top dielectric layer 212c is silicon oxide, for example, and the thickness of the top dielectric layer is about 30 angstroms to about 60 angstroms. The material of the charge trapping layer 212 can also be any other materials that comprise the charge trapping function.

The plurality of control gates 214a to 214d are disposed on the composite dielectric layer 212, filling the gaps between the stacked gate structures 202a to 202e. Further, the control gates 214a to 214d are connected together by the control gate line 214. The plurality of the control gates 214a to 214d and the control gate line 214 are integrated together, for example. In other words, the plurality of the control gates 214a to 214d extends to above the stacked gate structures 202a to 202e and is connected to the stacked gate structure to form the control gate line 214. The control gate line 214 is substantially perpendicular to the stacked gate structures 202a to 202e, for example. The material of the control gates is doped polysilicon, for example.

The plurality of stacked gate structures 214a to 214d, the spacer 210, the composite dielectric layer 212, the plurality of control gates 214a to 214d constitute a row of the memory cells 220. The source region 218 and the drain region 216 are respectively disposed in the substrate 200 beside both sides of the row of the memory cells 220. For example, the drain region 216 is disposed in the substrate 200 beside one side of the stacked gate structure 202a of the row of the memory cells 220, while the source region 218 is disposed in the substrate 200 beside one side of the stacked gate structure 202e of the row of the memory cells 220. In other words, the drain region 216 and the source region 218 are disposed in the substrate 200 respectively beside the sides of the two outer stacked gate structures 202a, 202e.

In the structure of the above row of memory cells, each of the control gates 214a to 214d and the composite dielectric layer 212 form the memory cell structure 222a to 222d, respectively, and each of the stacked gate structures 202a to 202d form the memory cell structure 222a to 222d, respectively. The stacked gate structure 202 disposed closest to the source region 218 serves as a switch transistor, for example. Since there is not gap in between the memory cell structures 222a to 222d and the stacked gate structures 202e, the level of integration of memory cells can be increased. Further, the conductive layer 214f and the conductive layer 214e above the source region and the drain region are not used as control gates. The composite dielectric layer 212 disposed above the source region 216 and the drain region 218 can insulate the conductive layer 214f from the drain region 218, and the conductive layer 214e from the source region 216, respectively.

In the above row of memory cells, a charge trapping layer (silicon nitride) is used as a charge storing unit. The required operating voltage for an operation can be lower to enhance the operating speed and efficiency of the memory cell.

Although the above-mentioned embodiments refer to four memory cell structures 222a to 222d connecting together, it is to be understood that these embodiments are presented by way of example and not by way of limitation. In other words, the number of memory cell structures connecting together depends on the actual demand. For example, one common control gate line can connect 32 to 64 memory cell structures.

As shown in FIG. 2A, in the entire memory array, no isolation structure and no contact are formed between each row of the memory cells. The level of integration of the memory array can be increased.

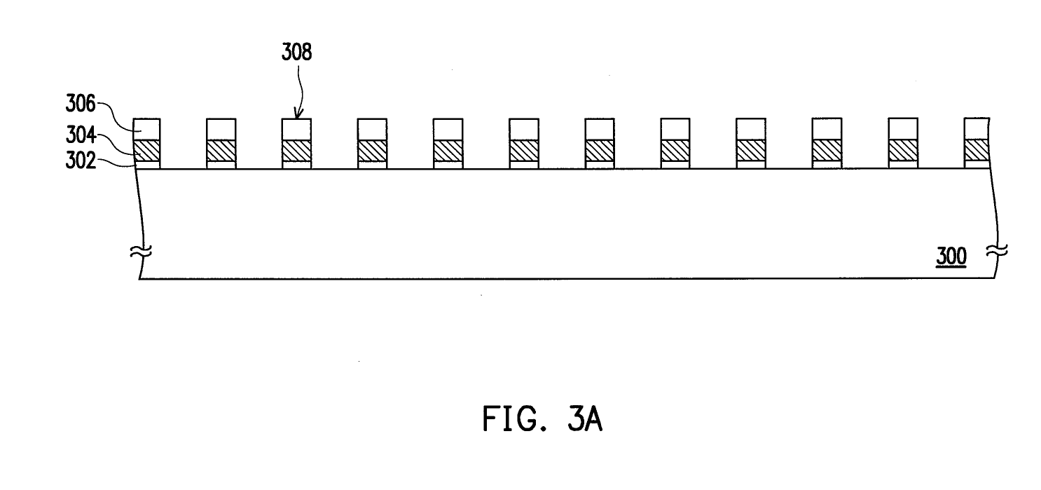

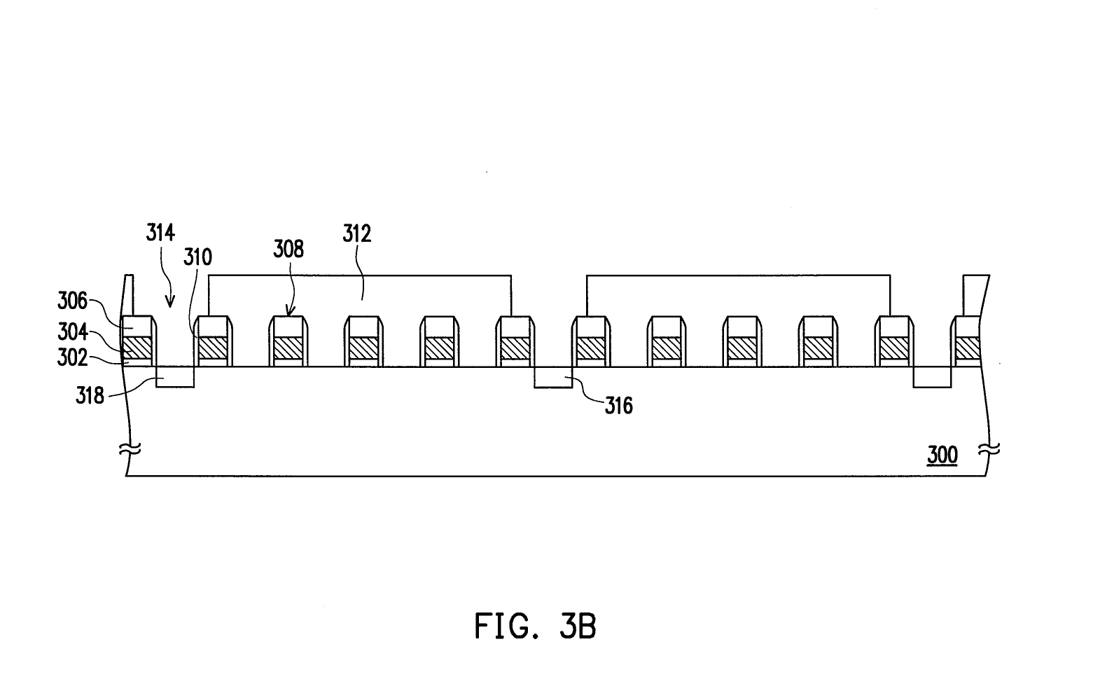

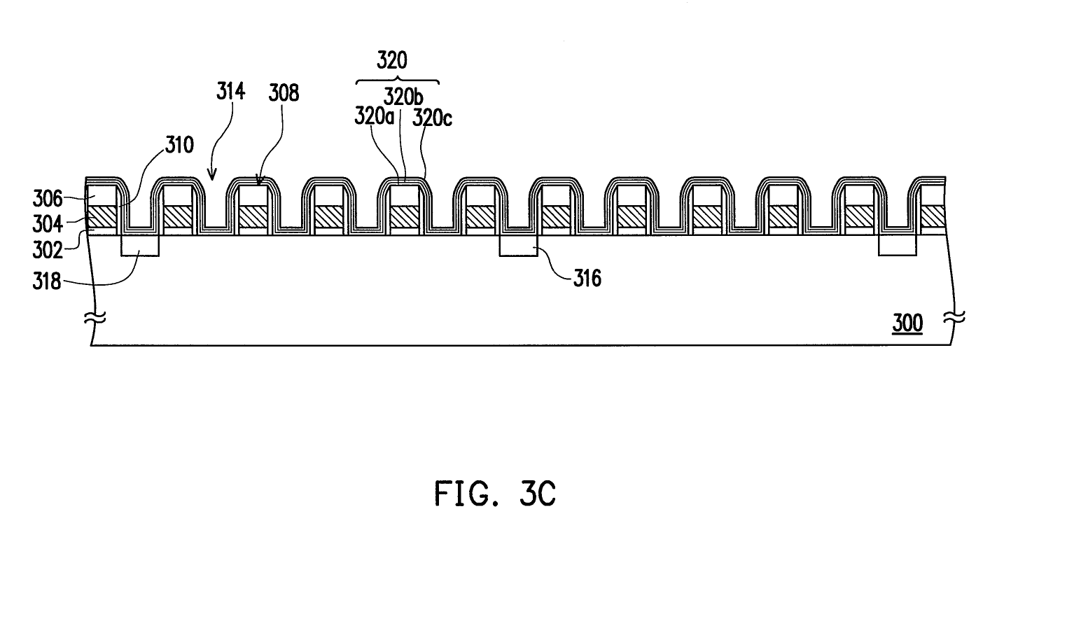

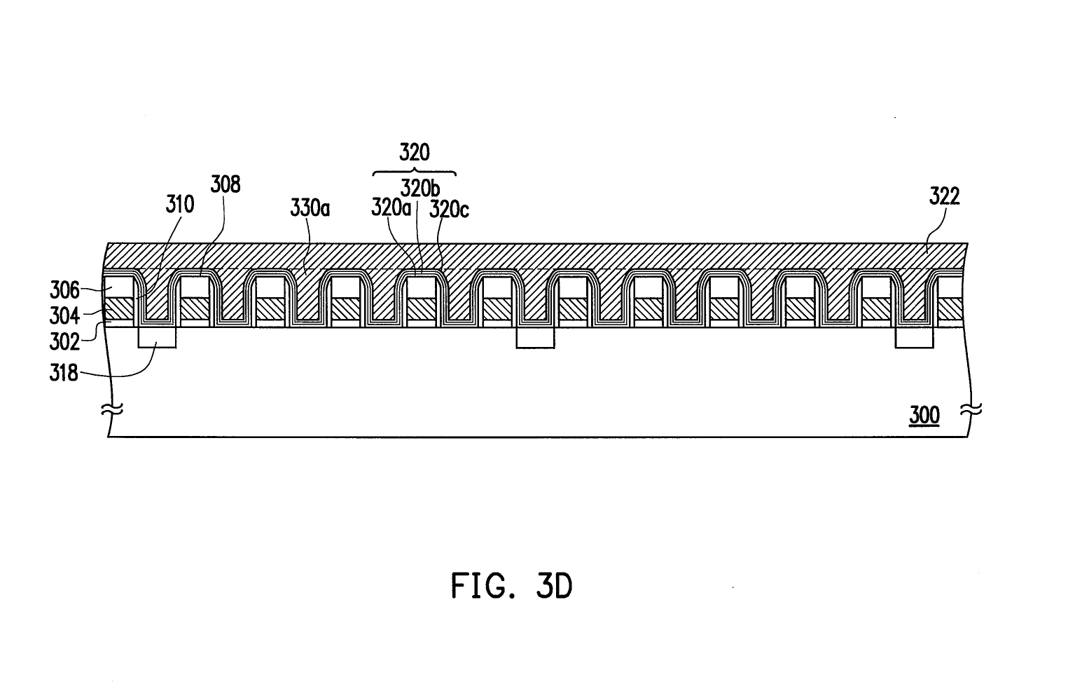

A method for fabrication a memory array according to the present invention is disclosed herein. FIGS. 3A to 3E are schematic diagram along the cutting line A-A′ of FIG. 2A showing the steps for fabricating a non-volatile memory according to an embodiment of the present invention.

Referring to FIG. 3A, a substrate 300 is provided. The substrate 300 is a silicon substrate, for example. A dielectric layer 302, a conductive layer 304 and a cap layer 306 are sequentially formed on the substrate 300 to form a plurality of stacked gate structures 308. Forming the stacked gate structures 308 include sequentially forming a dielectric layer, a conductive layer and a cap layer over the substrate 300, followed by performing a photolithography and etching process. The material of the dielectric layer includes silicon oxide, for example, and is formed by thermal oxidation. The material of the conductive layer includes doped polysilicon. The conductive layer is formed by forming an undoped polysilicon layer with chemical vapor deposition, followed by performing an ion implantation process. The cap layer is formed with silicon oxide, for example, by reacting tetraethyl orthosilicate (TEOS)/ozone (O₃) in a chemical vapor deposition process. The conductive layer 304 serves as a select gate, while the dielectric layer 302 serves as a select gate dielectric layer.

Referring to FIG. 3B, a spacer 310 is formed on the sidewall of each stacked gate structure 308. The material of the spacer 310 includes silicon oxide or silicon nitride. The spacer 310 is formed by forming an insulation material layer on the substrate 300, followed by performing an anisotropic etching process. A mask layer 312 is then formed over the substrate 300. The mask layer 312 has an opening 314 exposing the part of the substrate 300 predetermined for forming the source region 316 and the drain region 318. The material of the mask layer is a photoresist material, for example. Further using the mask layer 312 as a mask, the source region 316 and the drain region 318 are formed in the substrate 300. The source region 316 and the drain region 318 are formed by ion implantation, for example. The source region 316 and the drain region 318 are separated by at least two stacked gate structures 308.

Referring to FIG. 3C, after removing the mask layer 312, a composite dielectric layer 320 is formed over the substrate 300. The composite dielectric layer 320 is formed with, from bottom to top, a bottom dielectric layer 320a, a charge trapping layer 320b and a top dielectric layer 320c. The bottom dielectric layer 320a is formed with silicon oxide, for example, while the charge trapping layer 320b is formed with a material includes but not limited to silicon nitride. The material of the top dielectric layer 320c includes silicon oxide, for example. The composite dielectric layer 320 is formed by, for example, performing chemical vapor deposition to sequentially form the bottom dielectric layer 320a, the charge trapping layer 320b and the top dielectric layer 320c. On the other hand, the composite dielectric layer 320 can also form by performing thermal oxidation to form the bottom dielectric layer 320a, followed by performing chemical vapor deposition to form the charge trapping layer 320b and the top dielectric layer 320c. If thermal oxidation is used to form the bottom dielectric layer 320a, the bottom dielectric layer 320a formed on the surface of the source region 316 and the drain region 318 is thicker than the bottom dielectric layer 320a formed at other region. This is due to the fact that the source region 316 and the drain region 318 are doped with dopants and their oxidation rate is faster than other regions not doped with dopants. Accordingly, the bottom dielectric layer 320a at the source region 316 and the drain region 318 are thicker.

Continuing to FIG. 3D, a conductive layer (not shown) is formed on the substrate 300, and the conductive layer fills the gaps between the stacked gate structures 308. The conductive layer is formed by forming a conductive material layer on the substrate 300, followed by using chemical mechanical polishing or back etching to planarize the conductive material layer. The conductive material layer is a doped polysilicon layer, for example, and is formed by performing chemical vapor deposition to form a layer of undoped polysilicon layer, followed by performing an ion implantation process. Thereafter, the conductive layer is patterned to form a control gate line 322 (word line), wherein the control gate line 322 (word line) fills the gap between the stacked gate structures 308. Beside the control gate line positioned above the source region 316 and the drain region 318, the control gate line 322 positioned in the gap between two neighboring stacked gate structures serves as a control gate 330a. In other words, the control gate 330a extends to the surface of the stacked gate structure 308 to connect with the stacked gate structure 308. The subsequent fabrication process of a memory array is well known to those skilled in the art; therefore, the detail thereof will not be reiterated herein.

In the above row of memory cells, the charge trapping layer (silicon nitride) serves as the charge storing unit. The operating voltage required for an operation can be lower to increase the operating speed and efficiency of the memory cell.

Comparing the process in which a charge trapping layer (silicon nitride) is formed as a charge storing unit with the process in which a floating gate (doped polysilicon) is formed as a charge storing unit, the step for defining the floating gate can be reduced. Accordingly, the process of the invention is simpler and the level of integration is improved.

Although the above-mentioned embodiments refer to four memory cell structures 222a to 222d connecting together, it is to be understood that these embodiments are presented by way of example and not by way of limitation. In other words, the number of memory cell structures connecting together depends on the actual demand. For example, one common control gate line can connect 32 to 64 memory cell structures.

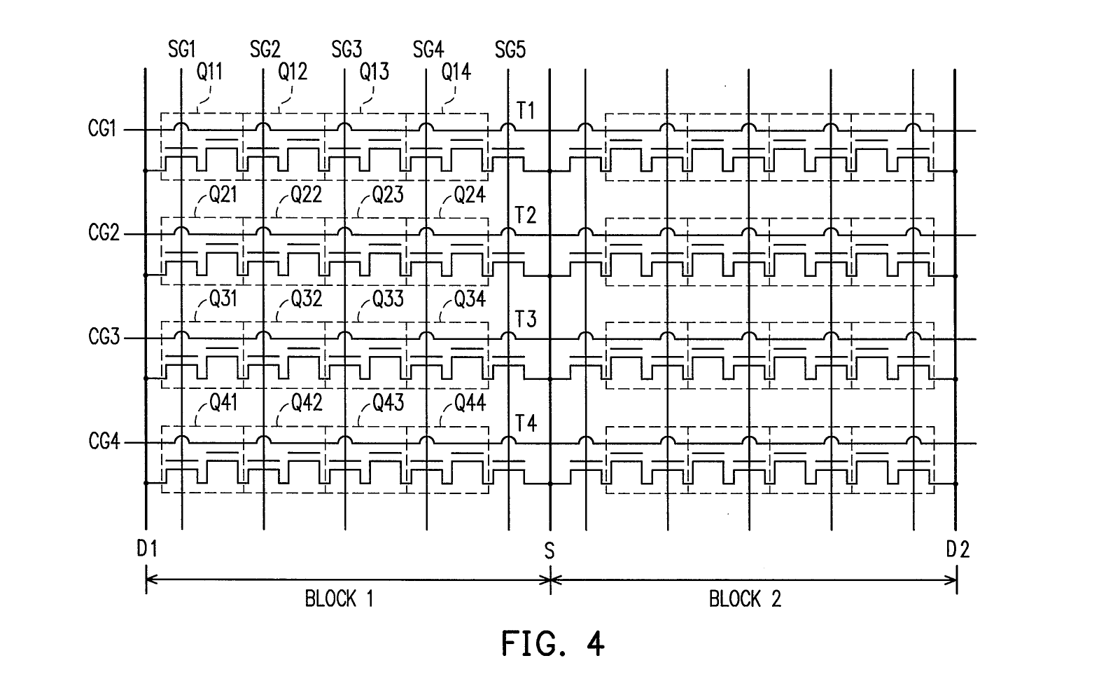

FIG. 4 is a simplified circuit diagram of the memory array of the present invention. FIG. 4 is divided into memory block BLOCK1 and memory block BLOCK2. The memory block BLOCK1 is used herein to illustrate the operation of the memory array of the present invention; and as an example, the memory block BLOCK1 has 16 memory cells.

Referring to FIG. 4, the rows of memory cells includes 16 memory cells Q11 Q44, (LOCOS), switch transistors T1 to T4, select gate lines SG1 to SG5, control gate lines CG1 to CG4, a source line D and a drain line D.

Each of the memory cells Q11 to Q44 includes a select gate, a control gate and a charge trapping layer.

The source line S and the drain line D extend along the direction of the column of the array. Each row of the memory cells includes four memory cells and a switch transistor connected together. For example, the memory cells Q11 to Q14 and the switch transistor T1 are connected together; the memory cells Q21 to Q24 and the switch transistor T2 are connected together; the memory cells Q31 to Q34 and the switch transistor T3 are connected together; the memory cells Q41 to Q44 and the switch transistor T4 are connected together.

Each of the control gate lines CG1 to CG4 connects the control gates along the same row of the memory cells. For example, the control gate line CG1 connects the control gates of the memory cells Q11 to Q14; the control gate line CG2 connects the control gates of the memory cells Q21 to Q24; the control gate line CG3 connects the control gates of the memory cells Q31 to Q34; the control gate line CG4 connects the control gates of the memory cells Q41 to Q44.

Each of the select gate lines SG1 to SG4 connects the select gates along the same column of the memory cells. For example, the select gate line SG1 connects the select gates of the memory cells Q11 to Q41; the select gate line SG2 connects the select gates of the memory cells Q12 to Q44; the select gate line SG3 connects the select gates of the memory cells Q13 to Q43; the select gate line SG1 connects the select gates of the memory cells Q14 to Q44; the select gate line SG5 connects the gates of the switch transistors T1 to T4 along a same column.

Although the disclosure hereafter refers to certain embodiments for illustrating the operating method of the non-volatile memory of the present invention, it is to be understood that these embodiments are presented by way of example and not by way of limitation.

Memory cell Qn2 is used herein to illustrate the programming operation of the invention. A bias voltage of 5 volts is applied to the source lines. A bias voltage of 1.5 volts is applied to the selected select gate line SG2, while a bias voltage of about 8 volts is applied to the non-selected select gate lines SG1, SG3, SG4. A bias voltage of about 8 volts is applied to the select gate line SG5. A bias voltage of about 7 volts is applied to the selected control gate line CG1, while a bias voltage of about 0 to 2 volts is applied to the non-selected control gate lines CG2, CG3, CG4. The substrate and the drain line are grounded. Source-side injection (SSI) is used to inject electrons into the charge trapping layer of the memory cell to program the memory cell Qn2.

During a reading operation, a bias voltage of about 0 volt is applied to the source line; a bias voltage of about 4.5 volts is applied to the select gate lines SG1 to SG5, respectively; a bias voltage of about 3 volts is applied to the control gate line CG1; and a bias voltage of 2 volts is applied to the drain line. Since the channel of the memory cell is closed and the current is small when the total amount of charges in the charge trapping layer is negative, and the channel is opened and the current is large when the total amount of charges in the charge trapping layer is slightly positive, the opening or closing/large or small current flow at the channel can be used to determine the digital information stored in the memory cell is “1” or “0”.

During the erasing operation, a bias voltage of about −20 volts is applied to the control gate line CG1 and a bias voltage of about 0 volt is applied to the substrate. The channel F-N tunneling is used to pull the electrons from the charge trapping layer of the memory cell to erase the information in the memory cell.

The operation of the memory array includes using the hot carrier effect to program a single memory cell with a single bit as a unit, and the channel F-N tunneling to erase the entire array of the memory cells. Accordingly, the electron injection rate is higher to lower the current flow of the memory cell during an operation. Further, the operating rate is concurrently increased. Therefore, the current consumption is small to effectively lower the power consumption of the entire wafer.

Further, in the above memory array, the charge trapping layer (silicon nitride) is used as a charge storing unit. The operating voltage required for an operation can thereby lowered and the operating speed and efficiency of the memory cell are improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate;
a first row of memory cells disposed on the substrate, the first row of the memory cells comprising:
a plurality of stacked gate structures disposed on the substrate, each of the stacked gate structures comprising a select gate dielectric layer, a select gate and a cap layer sequentially disposed from the substrate and a spacer disposed on a sidewall;
a composite dielectric layer, disposed on a surface of the substrate between every two stacked gate structures and on a surface of the stacked gate structures, wherein the composite dielectric layer comprises a bottom dielectric layer, a charge trapping layer and a top dielectric layer;
a control gate line disposed on the composite dielectric layer, filling the gaps between the every two stacked gate structures; and
a first source region/drain region and a second source/drain region disposed in the substrate respectively beside two sides of the first row of the memory cells.

2. The non-volatile memory of claim 1, wherein a material constituting the charge trapping layer comprises silicon nitride.

3. The non-volatile memory of claim 1, wherein a material constituting the bottom dielectric layer and the top dielectric layer comprises silicon oxide.

4. The non-volatile memory of claim 1, wherein a material constituting the select gate line comprises doped polysilicon.

5. The non-volatile memory of claim 1, wherein a material constituting the control gate line comprises doped polysilicon.

6. The non-volatile memory of claim 1 further comprising:
a second row of memory cells, disposed on the substrate, wherein structures of the second row of the memory cells and the first row of the memory cell are substantially the same; and
the second source region/drain region and a third source region/drain region are disposed in the substrate respectively beside two sides of the second row of the memory cells, wherein the second row of the memory cells and the first row of the memory cell share the second source region/drain region.

7. A non-volatile memory array, comprising:
a substrate;
a plurality of rows of memory cells, the rows of the memory cells arranging in a memory array, the memory array comprising:
a plurality of stacked gate structures disposed on the substrate, each stacked gate structure comprising, sequentially from the substrate, a select gate dielectric layer and a select gate;
a composite dielectric layer disposed on and conformal to a surface of gaps between every two of the stacked gate structures, the composite dielectric layer includes a bottom dielectric layer, a charge trapping layer and a top dielectric layer;
a plurality of control gates disposed on the composite dielectric layer, wherein the control gates fill the gaps between the every two of the stacked gate structures; and
a source region/drain region disposed in the substrate respectively on one side of the outer two stacked gate structures;
a plurality of control gate lines connecting the control gates along a same row;
a plurality of select gate lines connecting the select gates along a same column;
a plurality of source lines connecting source regions along a same column; and
a plurality of drain lines connecting drain regions along a same column.

8. The non-volatile memory of claim 7, wherein a material of the charge trapping layer comprises silicon nitride.

9. The non-volatile memory of claim 7, wherein a material constituting the bottom dielectric layer and the top dielectric layer comprises silicon oxide.

10. The non-volatile memory of claim 7, wherein a material constituting the select gates comprises doped polysilicon.

11. The non-volatile memory of claim 7, wherein a material constituting the control gates comprises doped polysilicon.

12. The non-volatile memory of claim 7, wherein the memory array at least divides into a first memory block and a second memory block, wherein the drain regions of the rows of the memory cells in the first memory block region are connected together through a first drain line, the drain regions of the rows of the memory cells in the second memory block are connected together through a second drain line, and the first memory block and the second memory block share a source line.

13. The non-volatile memory cell of claim 7 further comprising a cap layer disposed o the select gate.

14. The non-volatile memory cell of claim 7 further comprising a spacer disposed on a sidewall of each stacked gate structure.
